(19) United States
(12) Patent Application Publication
(10) Pub. No.: US 2015/0243483 A1
(43) Pub. Date: Aug. 27, 2015

(54) TUNABLE RF FEED STRUCTURE FOR PLASMA PROCESSING

(71) Applicant: Lam Research Corporation, Fremont, CA (US)

(72) Inventors: Zhigang Chen, Campbell, CA (US); Rajinder Dhindsa, San Jose, CA (US)

(73) Assignee: Lam Research Corporation, Fremont, CA (US)

(21) Appl. No.: 14/187,163

(22) Filed: Feb. 21, 2014

(51) Int. Cl. H01J 37/32; H01L 21/67

(52) U.S. Cl. CPC H01J 37/3211; H01J 37/32568; H01J 37/32715; H01J 37/32183; H01L 21/67017; H01J 2237/332; H01J 2237/334; H01J 2237/335

(57) ABSTRACT

A chamber for plasma processing semiconductor wafers is provided, comprising: a support chuck disposed in the chamber; a top electrode disposed over the support chuck and within the chamber; an RF supply rod electrically connected between an RF power source and the support chuck for providing RF power to the chamber, the RF supply rod having a corrugated surface, the corrugated surface having recessed and protruded regions that are arranged in a lengthwise repeating pattern along a segment of the RF supply rod, the corrugated surface producing a lengthwise minimum surface path along the segment that is greater than a length of the segment, the lengthwise minimum surface path defining a target length of the RF supply rod.

### FIELD OF THE INVENTION

The present invention relates generally to semiconductor fabrication, and more particularly, to a tunable RF feed structure for plasma processing.

### DESCRIPTION OF THE RELATED ART

In semiconductor manufacturing, plasma processes are commonly and repeatedly carried out. A plasma typically contains various types of radicals, as well as positive and negative ions. The chemical reactions of the various radicals, positive ions, and negative ions are used to perform various operations in the fabrication of semiconductor devices, including etching, deposition, cleaning, ashing, etc. By way of example, during an etching process, a chamber coil performs a function analogous to that of a primary coil in a transformer, while the plasma performs a function analogous to that of a secondary coil in the transformer.

For a given plasma process chamber, the chamber impedance and the chamber's frequency characteristics are often not optimized for a given plasma processing operation. Furthermore, it is difficult to change such characteristics because of limitations imposed by the chamber dimensions, footprint, and serviceability of the chamber.

The length (or longitudinal dimension) and width (or transverse dimension) of the RF feed structure for a plasma process chamber significantly impact chamber impedance and frequency characteristics. Further, it is known that chamber impedance and frequency characteristics (such as resonances) play a critical role in determining chamber operation stability, RF power coupling efficiency, and on-wafer performance (e.g. radial etch rate non-uniformity at very high frequencies and their higher harmonics). However, changing the length and width of the RF feed structure for the chamber is challenging due to the chamber dimensions and footprint, which impose limitations on the length and width of the RF feed structure.

It is in this context that embodiments of the invention arise.

### SUMMARY

Disclosed is an RF feed structure for plasma processing that is tunable to enable optimization of chamber impedance and its frequency characteristics without altering chamber dimensions, footprint, or other parts of the chamber system.

In one embodiment, a chamber for plasma processing semiconductor wafers is provided, comprising: a support chuck disposed in the chamber; a top electrode disposed over the support chuck and within the chamber; an RF supply rod electrically connected between an RF power source and the support chuck for providing RF power to the chamber, the RF supply rod having a corrugated surface, the corrugated surface having recessed and protruded regions that are arranged in a lengthwise repeating pattern along a segment of the RF supply rod, the corrugated surface producing a lengthwise minimum surface path along the segment that is greater than a length of the segment, the lengthwise minimum surface path defining a target length of the RF supply rod.

In one embodiment, the protruded regions are defined by disc-shaped portions of the RF supply rod having a first diameter.

In one embodiment, the recessed regions are defined by disc-shaped portions of the RF supply rod having a second diameter, the second diameter being less than the first diameter, and the protruded regions and recessed regions alternate along the segment of the RF supply rod.

In one embodiment, the RF supply rod is at least partially within the chamber.

In one embodiment, the RF supply rod is disposed within a grounded conductive tube.

In one embodiment, a space is defined between the RF supply rod and the grounded conductive tube.

In one embodiment, a dielectric is defined between the RF supply rod and the grounded conductive tube.

In one embodiment, the rod is defined by more than one segment, the more than one segment being defined as a single piece or multiple pieces.

In one embodiment, the RF supply rod connects to a lower base of the chamber that is electrically coupled to the support chuck.

In one embodiment, the RF supply rod couples to a RF match circuit, wherein the match circuit is coupled to an RF power supply.

In one embodiment, the RF supply rod connected between the RF match circuit and the chuck is at least part of an electrical length that is tuned with the match circuit.

In one embodiment, the RF supply rod provides RF power in a direction that is towards the chuck and a return path for ground is provided through the grounded conductive tube.

In one embodiment, the electrical length is adjustable by modifying the corrugated surface to have fewer or more recessed regions or protruding regions.

In one embodiment, a second segment of the RF supply rod defines a hollow conductive region.

In one embodiment, the corrugated surface defines an effective electrical path for said segment, the effective electrical path being defined to traverse a contour of the corrugated surface, the effective electrical path being greater than the length of said segment.

### BRIEF DESCRIPTION OF THE DRAWINGS

The invention, together with further advantages thereof, may best be understood by reference to the following description taken in conjunction with the accompanying drawings.

FIG. 1 illustrates a cross-sectional view of a plasma processing system, in accordance with an embodiment of the invention.

FIG. 2 illustrates a cross-sectional view of a portion of an RF feed structure, in accordance with an embodiment of the invention.

FIG. 3 illustrates a cross-sectional view of a portion of an RF feed structure, showing various dimensional aspects, in accordance with an embodiment of the invention.

FIG. 4 is a graph of input impedance magnitude (Ohm) vs. RF Frequency (MHz) for a plasma processing chamber, in accordance with an embodiment of the invention.

FIGS. 5A to 5K illustrate various configurations of an RF supply rod, demonstrating various surface corrugation patterns, in accordance with embodiments of the invention.

### DETAILED DESCRIPTION

Disclosed is a tunable RF feed structure for plasma processing. The RF feed structure can be tuned to optimize the chamber impedance and its frequency characteristics without changing the chamber dimensions or other parts of the chamber. In one embodiment, the RF feed structure connects to an RF match. Broadly speaking, the RF feed structure defines a coaxial transmission line having an RF supply rod disposed within a surrounding ground cylinder. The surface of the RF supply rod is corrugated, which provides for an effective electrical length that is greater than the length of the segment of the RF supply rod that is corrugated. In one embodiment, the RF supply rod also includes a segment that is configured as a hollow cylinder, which is configured to reduce thermal conduction.

In the following description, numerous specific details are set forth in order to provide a thorough understanding of the present invention. However, it will be apparent to one skilled in the art that the present invention may be practiced without some of these specific details. In other instances, well known process operations and implementation details have not been described in detail in order to avoid unnecessarily obscuring the invention.

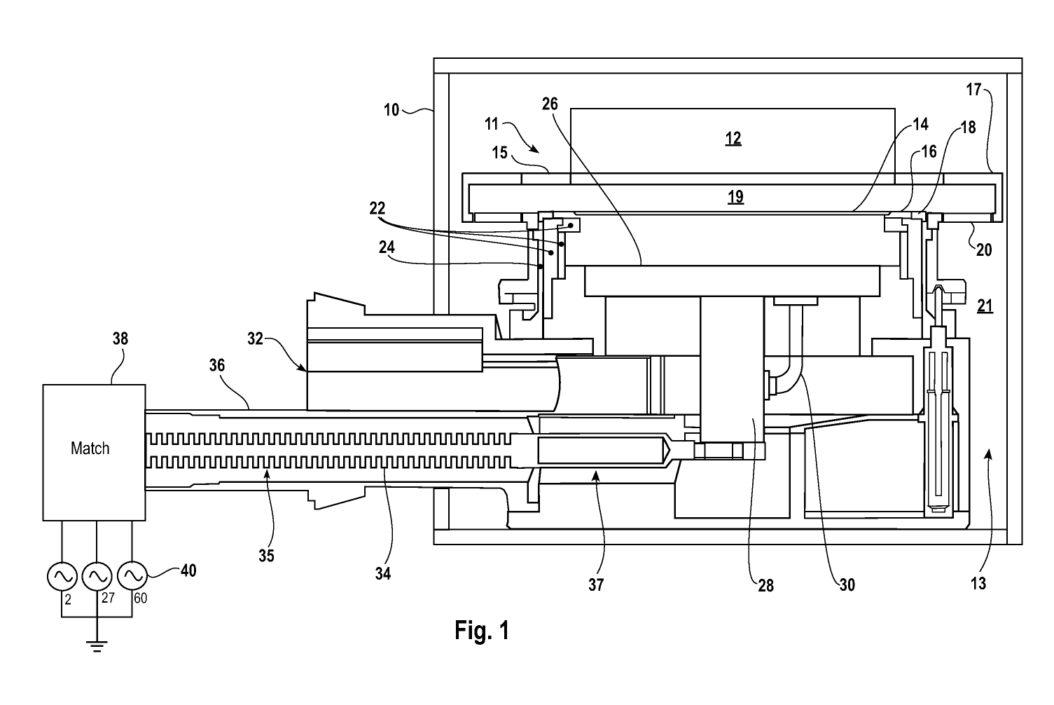

FIG. 1 illustrates a cross-sectional view of a plasma processing system, in accordance with an embodiment of the invention. The system includes a process chamber 10, in which a wafer may undergo a plasma processing operation. It will be appreciated that the process chamber 10 may include a gate or door (not shown) through which a wafer may be transferred in to or out of the chamber 10. Housed within the process chamber 10 are various components described below.

Broadly speaking, components disposed within the process chamber 10 define a top assembly 11 and a bottom assembly 13. In the illustrated configuration, the top assembly and bottom assembly are shown in a closed configuration, as would be the case during plasma processing. In the closed configuration, an inner chamber 19 is defined in which wafer processing takes place. Additionally, in the closed configuration, an outer chamber 21 is defined, through which reaction byproducts and process gas are exhausted from the system. It will be appreciated that the top and bottom assembly can be opened to permit wafer transfer. In one embodiment, the top assembly is configured to be raised and lowered, thereby respectively defining open and closed configurations.

The top assembly 11 includes a top electrode 12 which is grounded. The top electrode 12 can be a showerhead structure having conduits or pores defined therein which as configured to provide even distribution of process gas to the surface of the wafer. An outer electrode 15 is defined adjacent to the top electrode 12. A shroud 17 is a structure defining the outer rim of the top assembly. The shroud 17 can include exhaust screen 20, which is a porous structure permitting gas to be exhausted from the inner chamber 19.

The bottom assembly 13 includes chuck 14 which is configured to support a wafer for processing. The chuck 14 may include lift pins (not shown) for lifting the wafer from the chuck. Additionally, the chuck 14 includes cooling ducts in which coolant (e.g. water) is circulated to cool the chuck and by extension, the wafer. A coolant fitting 30 is shown, configured to deliver coolant to the cooling ducts. A facilities plate 26 is positioned below the chuck 14, and is configured to support various facilities which are provided to the chuck, such as actuators for moving the lift pins, coolant feed and return lines, etc. It will be appreciated that the chuck 14 can be further configured to provide additional features, such as vacuum suction or electrostatic attraction for securing the wafer to the chuck. Various supply and return lines, communication lines, AC power lines, etc. are provided to the facilities plate via a facilities conduit shown at reference 32.

A focus ring 16 is provided for controlling the incidence angle of ions at the wafer edge and therefore controlling etch profile integrity. A quartz insulator 18 as well as additional insulators 22 are also shown. A ground ring 24 is positioned surrounding the chuck and provides RF return path.

RF power is generated by an RF power source 40, which connects to match circuitry 38. The RF power source 40 is configured to provide a desired frequency of RF power. In some embodiments, there are multiple RF power sources configured to provide different frequencies. In one embodiment, there are RF power sources configured to provide RF power at frequencies of 2 MHz, 27 MHz, and 60 MHz. In one embodiment, the RF frequency is in the range of about 100 kHz to about 200 MHz.

An RF feed structure is defined to include an RF supply rod 34 and a ground tube 36, both of which connect to the match circuitry 38. The RF supply rod 34 is disposed within the ground tube 36 so as to define a coaxial transmission line. The RF supply rod 34 connects to an RF bracket 28, which together define an electrical delivery path for delivering RF power to the chuck 14.

As shown with continued reference to FIG. 1, the RF supply rod includes a segment having a corrugated surface (ref. 35), and a segment which is defined as a hollow tube (ref. 37). The corrugated surface effectively increases the electrical path length as compared to the end-to-end length of that segment of the RF supply rod having the corrugated surface. The corrugated surface thereby also effectively increases the electrical length of the RF supply rod as a whole.

The dimensions and shape of the corrugated surface can be tuned to optimize the chamber impedance and its frequency response characteristics to improve chamber operation stability, RF power coupling efficiency, and on-wafer performance such as radial non-uniformity. The RF feed structure is partially disposed within the chamber 10 and partially disposed outside the chamber 10.

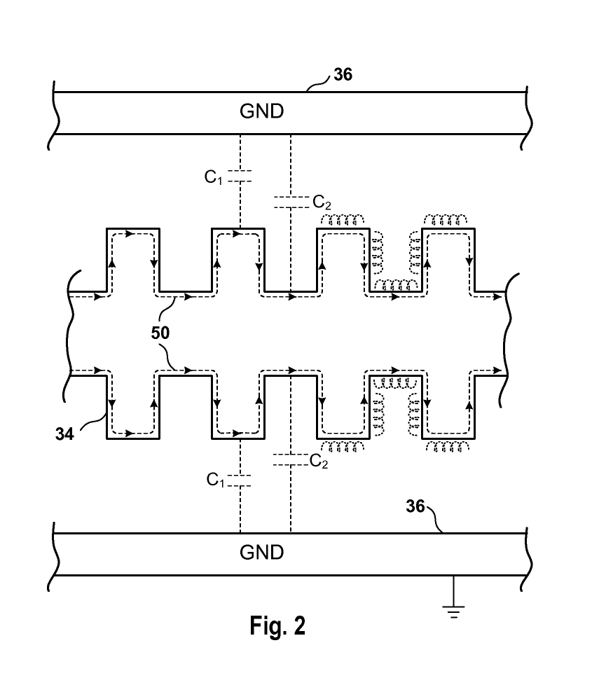

FIG. 2 illustrates a cross-sectional view of a portion of an RF feed structure, in accordance with an embodiment of the invention. In the illustrated embodiment, a portion of the RF supply rod 34 is shown, as well as a portion of the ground tube 36 which surrounds the RF supply rod. Due to the skin effect, current is distributed within the RF supply rod in a manner such that current density is greatest near the surface of the RF supply rod and most of the current is concentrated within a thin layer of the rod surface. Thus, the current flow (ref. 50) generally follows the contours of the surface of the RF supply rod 34.

The shunt capacitance and the series inductance are affected by the dimensions of the corrugated structure of the RF supply rod. These would affect the effective electrical length of the RF supply rod and the overall chamber impedance.

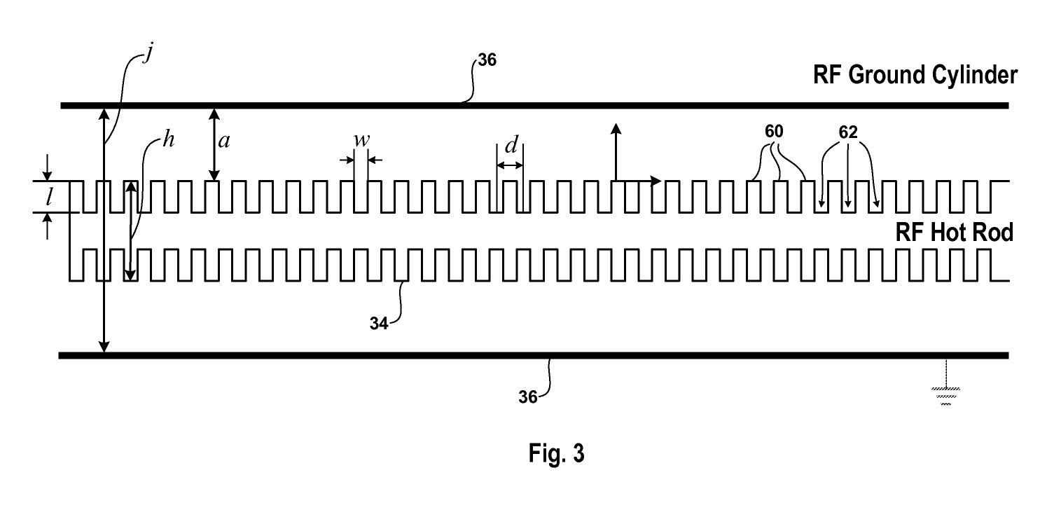

FIG. 3 illustrates a cross-sectional view of a portion of an RF feed structure, showing various dimensional aspects, in accordance with an embodiment of the invention. In the illustrated embodiment, the RF supply rod 34 is shown having a corrugated surface structure that is defined by protruded regions (ref. 60) and recessed regions (62) arranged in an alternating repeating pattern. As shown by the illustrated view, the lengthwise cross-section of the surface pattern is substantially similar to a rectangular wave.

In some embodiments, the corrugated structure can be defined by the following dimensions. A depth 1 defines the difference in height between the protruded regions and the recessed regions, and is analogous to the wave height (twice the amplitude) in the case where the lengthwise cross-section of the surface pattern is (or approximates) a wave.

A width w defines a width of either a protruded region or a recessed region. It should be appreciated that in some embodiments, the protruded regions and the recessed regions may have the same width, whereas in other embodiments, the protruded regions and the recessed regions may have different widths. When the lengthwise cross-section of the surface pattern is (or approximates) a wave, then the width w is equivalent to one-half the wavelength.

A pitch d defines the length of one elementary unit of the corrugated surface, which is the length of one complete cycle of the surface pattern. For example, the pitch d may be determined by measuring the distance from the start of one protrusion to the start of the next protrusion along the corrugated surface. When the lengthwise cross-section of the surface pattern is (or approximates) a wave, then the pitch d is equivalent to the wavelength.

A gap distance a defines the distance from the outermost surface of the RF supply rod 34 to the interior surface of the ground tube 36. In other words, the gap distance a defines the distance from the top of the protruded regions to the interior surface of the ground tube 36.

The RF supply rod 34 has a diameter h which is defined as the diameter of the outermost surface of the RF supply rod.

The ground tube 36 has a diameter j which is defined as the diameter of the inner surface of the ground tube.

The aforementioned dimensions of the RF supply rod can be tuned to optimize the effective electrical length of the structure without changing the ground tube dimensions or the system size. It will be appreciated that these dimensions can be tuned to optimize the chamber impedance and its frequency characteristics (e.g. frequency response and resonance frequencies) to achieve a desired chamber configuration for a given process operation.

Generally speaking, it is contemplated that the diameter j is defined for the plasma processing system and is not subject to change thereafter for purposes of altering the impedance and frequency characteristics of the chamber. However, it will be appreciated that in alternative embodiments, the diameter j of the ground tube can be changed to alter the characteristics of the chamber.

It will be appreciated that the aforementioned dimensions may vary to a certain extent, and that any specific dimensions or ranges of such dimensions discussed herein are provided by way of example, and not by way of limitation. It should be understood that the specific dimensions may have any values which are suitable for configuring the plasma process chamber to achieve a desired outcome in terms of impedance and frequency characteristics. With this in mind, various exemplary dimensions are described below.

In one embodiment, the diameter j of the ground tube is in the range of about two to about four inches. In one embodiment, the diameter j of the ground tube is approximately three inches.

In one embodiment, the diameter h of the RF supply rod is in the range of about 0.5 to about two inches. In one embodiment, the diameter h is in the range of about one to about two inches. In one embodiment, the diameter h of the RF supply rod is approximately one inch.

In one embodiment, the depth 1 is in the range of about 0.1 to about 0.4 inches.

In one embodiment, the width w is in the range of about 0.1 to about 1 inch. In one embodiment, the width w is in the range of about 0.3 to about 0.6 inches. In one embodiment, the width w is approximately 0.5 inches.

In one embodiment, the pitch d is in the range of about 0.2 to about 2 inches. In one embodiment, the pitch d is in the range of about 0.5 to about 1.5 inches. In one embodiment, the pitch d is approximately one inch.

In one embodiment, the gap distance a is in the range of about 0.2 to about 1.5 inches. In one embodiment, the gap distance a is in the range of about 0.5 to about 1 inch.

It will be appreciated that the configuration of the RF supply rod can be imagined as a series of disc-shaped objects. To produce the illustrated corrugation, disc-shaped portions having a first diameter alternate with disc-shaped portions having a second diameter.

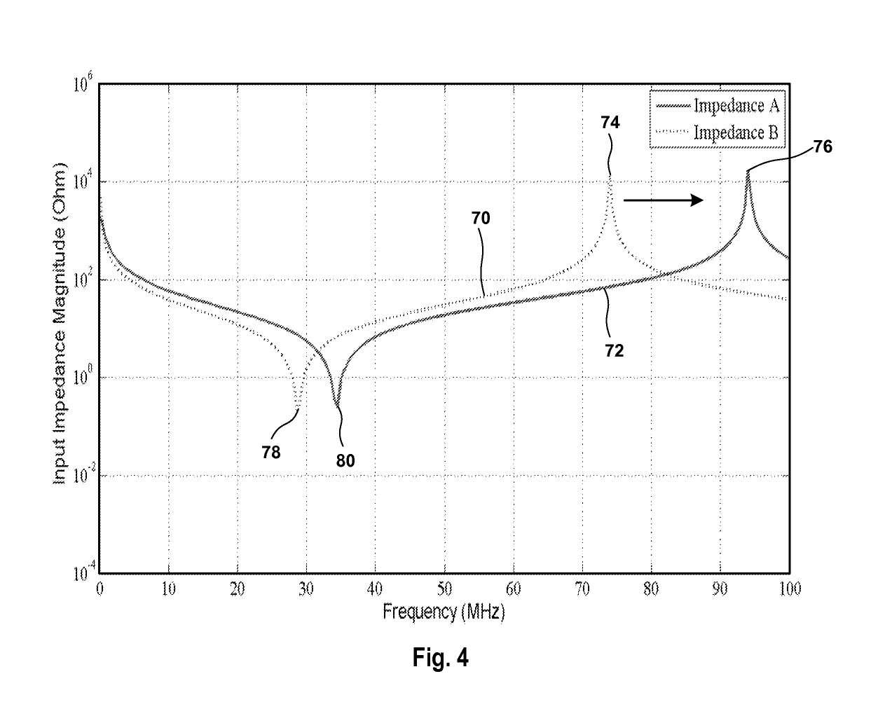

FIG. 4 is a graph of input impedance magnitude (Ohm) vs. RF Frequency (MHz) for a plasma processing chamber, in accordance with an embodiment of the invention. The illustrated graph shows the effect that tuning of the RF feed structure may have on the frequency characteristics of the chamber.

The curve 70 illustrates the impedance as a function of RF frequency for a first RF supply rod. As shown, the curve 70 exhibits resonance frequencies occurring at trough 78 and peak 74.

The curve 72 illustrates the impedance as a function of RF frequency for a second RF supply rod having different dimensions than the first RF supply rod. As shown, the curve 72 exhibits resonance frequencies occurring at trough 80 and peak 76.

As can be seen, the chamber impedance and frequency characteristics resulting from the application of the different RF supply rods results in different stable operating frequency ranges. Comparing the locations of the troughs and the peaks for the two curves, it can be seen that the resonance frequencies have been effectively shifted to higher frequencies, resulting in different stable operating ranges. A stable operating range can be defined as a frequency range over which the impedance magnitude varies by less than a predefined amount.

For example, the curve 70 (corresponding to application of the first RF supply rod) exhibits stable operating ranges of about 10 to about 20 MHz, and about 40 to about 60 MHz. Whereas, the curve 72 (corresponding to application of the second RF supply rod) exhibits stable operating ranges of about 10 to about 25 MHz, and about 50 to about 80 MHz. Thus, with first RF supply rod, it may not be desirable to operate in a frequency range approaching 25 MHz, whereas it is easier to do so with the second RF supply rod due to its greater stability in such a range. However, with the second RF supply rod, it may not be desirable to operate in a frequency range approaching 40 MHz; however, it is easier to do so with the first RF supply rod due to its greater stability in this range. In a similar manner, it may not be desirable with the first RF supply rod to operate in a frequency range approaching 70 MHz; yet it is easier to do so with the second RF supply rod because of its improved stability in this frequency range.

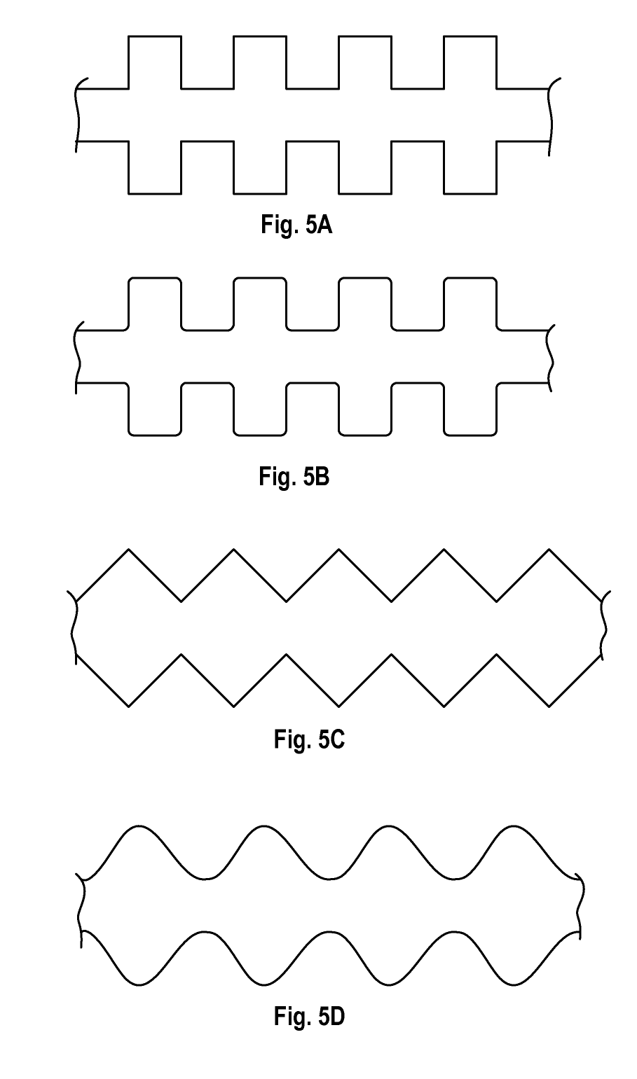

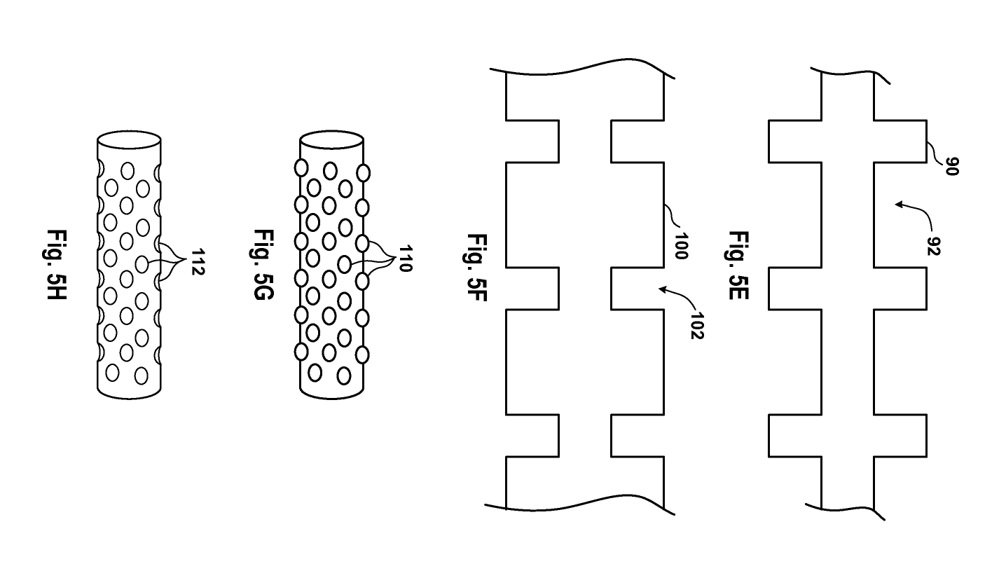

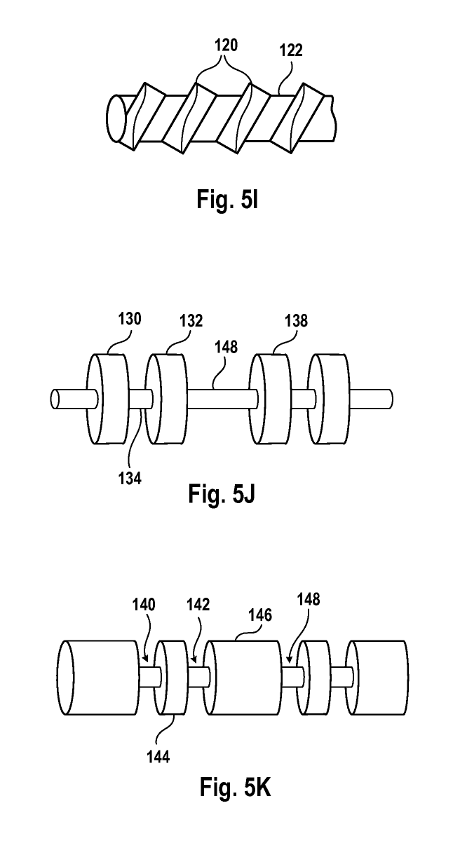

FIGS. 5A to 5K illustrate various configurations of an RF supply rod, demonstrating various surface corrugation patterns, in accordance with embodiments of the invention.

FIG. 5A illustrates a cross-sectional view of a segment of an RF supply rod, wherein the lengthwise (longitudinal) surface cross-section defines a substantially rectangular wave or substantially square wave.

FIG. 5B illustrates a cross-sectional view of a segment of an RF supply rod similar to that of FIG. 5A, except that the corner regions of the rectangular/square wave have been rounded to reduce the possibility of arcing.

FIG. 5C illustrates a cross-sectional view of a segment of an RF supply rod, wherein the lengthwise surface cross-section defines a substantially triangular wave.

FIG. 5D illustrates a cross-sectional view of a segment of an RF supply rod similar to that of FIG. 5C, except that the corner regions of the triangular wave have been rounded to reduce the susceptibility to arcing.

FIG. 5E illustrates a cross-sectional view of a segment of an RF supply rod, wherein the width of the protruded regions 90 is less than the width of the recessed regions 92.

FIG. 5F illustrates a cross-sectional view of a segment of an RF supply rod, wherein the width of the protruded regions 100 is more than the width of the recessed regions 102.

FIG. 5G illustrates an external view of a segment of an RF supply rod, wherein the surface contour is defined to include a pattern of protrusions 110. The pattern of protrusions is arranged so that the minimum lengthwise (longitudinal) surface path is greater than the length of the segment.

FIG. 5H illustrates an external view of a segment of an RF supply rod, wherein the surface contour is defined to include a pattern of recessions 112 (dimples). The pattern of recessions is arranged so that the minimum lengthwise (longitudinal) surface path is greater than the length of the segment.

FIG. 5I illustrates an external view of a segment of an RF supply rod having a screw-like configuration, wherein the surface contour is defined by a spiraling protrusion 120 about a central cylinder 122. It will be appreciated that the longitudinal surface cross-section would reveal a series of peaks alternating with a series of troughs.

FIG. 5J illustrates an external view of a segment of an RF supply rod, wherein protruded regions are arranged in clusters along the rod. In other words, alternating protruded regions and recessed regions are configured so that the protruded regions each have the same width, whereas the recessed regions do not have the same width from one recessed region to the next. In the illustrated embodiment, the widths of the recessed regions alternate between a shorter width and a longer width. In the illustrated embodiment, the successive protruded regions 130 and 132 are separated from each other by a recessed region 134. The protruded region 132 is separated from the protruded region 138 by a recessed region 136. The recessed region 136 has a width greater than that of recessed region 134. Successive protruded and recessed regions follow the same pattern.

FIG. 5K illustrates an external view of a segment of an RF supply rod wherein recessed regions are arranged in clusters along the rod. In other words, alternating recessed regions and protruded regions are configured so that the recessed regions each have the same width, whereas the protruded regions do not have the same width from one protruded region to the next. In the illustrated embodiment, the widths of the protruded regions alternate between a shorter width and a longer width. In the illustrated embodiment, the successive recessed regions 140 and 142 are separated from each other by a protruded region 144. The recessed region 142 is separated from the recessed region 148 by a protruded region 146. The protruded region 146 has a width greater than that of protruded region 144. Successive recessed and protruded regions follow the same pattern.

It should be appreciated that the specific geometry and shape of the surface corrugation of the RF supply rod may vary to a great extent in accordance with various embodiments. Though periodic structures have been presented herein, in alternative embodiments, non-periodic structures can be defined. The illustrated and described embodiments presented herein are to be understood as exemplary embodiments, without limitation. In various additional embodiments, the surface of the RF supply rod may be configured to have any contour or pattern of corrugation that is tuned to provide a desired chamber impedance and frequency characteristic.

In an alternative embodiment, the RF feed structure is configured so that the space between the grounded conductive tube and the RF supply rod is defined to include a dielectric material. Examples of suitable dielectric materials include quartz, Teflon, aluminum oxide, aluminum nitride, Ultem, and PEEK (PolyEtherEtherKetone).

The tunable RF feed structure disclosed herein provides several advantages over existing designs. The corrugation surface structures of the RF supply rod can be tuned to optimize chamber impedance and its frequency characteristics, such as frequency response and resonance frequencies. This can yield improvements in chamber operating stability, by providing broader or shifted stable operating frequency ranges, thereby permitting the chamber to exhibit improved performance for a desired operating frequencies of plasma process operations. Further, RF power coupling efficiency can be improved. For example, if reflections from the match circuitry are too high, then the RF supply rod can be tuned to provide optimal impedance. Additionally, the radial etch non-uniformity due to RF effects can also be improved by tuning the impedance to the proper range.

It will be appreciated that a variety of RF supply rods having different corrugation structures and electrical path lengths can be provided to an operator of the chamber, and one of the RF supply rods can be selected to provide the optimal impedance. Thus, instead of (or in addition to) tuning the RF power and match circuitry, the RF supply rod can be tuned to achieve improved power coupling efficiency.

While this invention has been described in terms of several embodiments, it will be appreciated that those skilled in the art upon reading the preceding specifications and studying the drawings will realize various alterations, additions, permutations and equivalents thereof. It is therefore intended that the present invention includes all such alterations, additions, permutations, and equivalents as fall within the true spirit and scope of the invention.

What is claimed is:

1. A chamber for plasma processing semiconductor wafers, comprising:
a support chuck disposed in the chamber;
a top electrode disposed over the support chuck and within the chamber;
an RF supply rod electrically connected between an RF power source and the support chuck for providing RF power to the chamber, the RF supply rod having a corrugated surface, the corrugated surface having recessed and protruded regions that are arranged in a lengthwise repeating pattern along a segment of the RF supply rod, the corrugated surface producing a lengthwise minimum surface path along the segment that is greater than a length of the segment, the lengthwise minimum surface path defining a target length of the RF supply rod.

2. The chamber of claim 1, wherein the protruded regions are defined by disc-shaped portions of the RF supply rod having a first diameter.

3. The chamber of claim 2, wherein the recessed regions are defined by disc-shaped portions of the RF supply rod having a second diameter, the second diameter being less than the first diameter, and the protruded regions and recessed regions alternate along the segment of the RF supply rod.

4. The chamber of claim 1, wherein the RF supply rod is at least partially within the chamber.

5. The chamber of claim 1, wherein the RF supply rod is disposed within a grounded conductive tube.

6. The chamber of claim 5, wherein a space is defined between the RF supply rod and the grounded conductive tube.

7. The chamber of claim 5, wherein a dielectric is defined between the RF supply rod and the grounded conductive tube.

8. The chamber of claim 1, wherein the rod is defined by more than one segment, the more than one segment being defined as a single piece or multiple pieces.

9. The chamber of claim 1, wherein the RF supply rod connects to a lower base of the chamber that is electrically coupled to the support chuck.

10. The chamber of claim 1, wherein the RF supply rod couples to a match circuit, wherein the match circuit is coupled to an RF power supply.

11. The chamber of claim 10, wherein the RF supply rod connected between the match circuit and the chuck is at least part of an electrical length that is tuned with the match circuit.

12. The chamber of claim 1, wherein the RF supply rod provides RF power in a direction that is towards the chuck and a return path for ground is provided through the grounded conductive tube.

13. The chamber of claim 1, wherein the electrical length is adjustable by modifying the corrugated surface to have fewer or more recessed regions or protruding regions.

14. The chamber of claim 1, wherein a second segment of the RF supply rod defines a hollow conductive region.

15. The chamber of claim 1, wherein the corrugated surface defines an effective electrical path for said segment, the effective electrical path being defined to traverse a contour of the corrugated surface, the effective electrical path being greater than the length of said segment.

16. A chamber for plasma processing semiconductor wafers, comprising:
a support chuck disposed in the chamber;
a top electrode disposed over the support chuck and within the chamber;
an RF supply rod electrically connected between an RF power source and the support chuck for providing RF power to the chamber, the RF supply rod having a corrugated surface, the corrugated surface having recessed and protruded regions that are arranged in a lengthwise repeating pattern along a segment of the RF supply rod, the corrugated surface producing a lengthwise minimum surface path along the segment that is greater than a length of the segment, the lengthwise minimum surface path defining a target length of the RF supply rod;
a grounded conductive tube, wherein the RF supply rod is disposed within the grounded conductive tube.

17. The chamber of claim 16,
wherein the RF supply rod connects to a lower base of the chamber that is electrically coupled to the support chuck;
wherein the RF supply rod couples to a match circuit, wherein the match circuit is coupled to an RF power supply.

18. The chamber of claim 16, wherein a second segment of the RF supply rod defines a hollow conductive region.

19. The chamber of claim 16, wherein the corrugated surface defines an effective electrical path for said segment, the effective electrical path being defined to traverse a contour of the corrugated surface, the effective electrical path being greater than the length of said segment.

20. A chamber for plasma processing semiconductor wafers, comprising:
a support chuck disposed in the chamber;
a top electrode disposed over the support chuck and within the chamber;
an RF supply rod electrically connected between an RF power source and the support chuck for providing RF power to the chamber, the RF supply rod having a corrugated surface, the corrugated surface having recessed and protruded regions that are arranged in a lengthwise repeating pattern along a segment of the RF supply rod, the corrugated surface producing a lengthwise minimum surface path along the segment that is greater than a length of the segment, the lengthwise minimum surface path defining a target length of the RF supply rod;
a grounded conductive tube, wherein the RF supply rod is disposed within the grounded conductive tube;
wherein the RF supply rod connects to a lower base of the chamber that is electrically coupled to the support chuck;
wherein the RF supply rod couples to a match circuit, wherein the match circuit is coupled to an RF power supply;
wherein a second segment of the RF supply rod defines a hollow conductive region;
wherein the corrugated surface defines an effective electrical path for said segment, the effective electrical path being defined to traverse a contour of the corrugated surface, the effective electrical path being greater than the length of said segment.
